(19) United States
(12) Patent Application Publication
(10) Pub. No.: US 2024/0330537 A1
(43) Pub. Date: Oct. 3, 2024

(54) DEVICE, METHOD AND PROGRAM FOR GENERATING POINT CLOUD DATA

(71) Applicant: NIPPON TELEGRAPH AND TELEPHONE CORPORATION, Tokyo (JP)

(72) Inventors: Yukihiro GOTO, Musashino-shi, Tokyo (JP); Mitsuyasu YANAGIDA, Musashino-shi, Tokyo (JP); Nazuki HONDA, Musashino-shi, Tokyo (JP)

(73) Assignee: NIPPON TELEGRAPH AND TELEPHONE CORPORATION, Tokyo (JP)

(21) Appl. No.: 18/576,083

(22) PCT Filed: Jul. 26, 2021
(86) PCT No.: PCT/JP2021/027596

§ 371 Date: Jan. 2, 2024

(51) Int. Cl. G06F 30/20; G06F 30/10

(52) U.S. Cl. CPC G06F 30/20; G06F 30/10

(57) ABSTRACT

An object of the present disclosure is to reduce a work time for creating correct data and to enable creation of correct data even for a target that does not exist in the actual environment.

The present disclosure is a device and method in which a correction value according to relative positions of a correction data acquisition object and a point cloud measuring instrument is calculated using correction point cloud data obtained by measuring the correction data acquisition object having a known shape with the point cloud measuring instrument and installation positions of the point cloud measuring instrument and the correction data acquisition object at a time of measuring the correction point cloud data; ideal point cloud coordinates obtained when a measurement target is measured with the point cloud measuring instrument are calculated using simulation data of the measurement target; and the ideal point cloud coordinates are corrected with a correction value according to relative positions of the measurement target and the point cloud measuring instrument to generate correct point cloud data simulating the measurement target.

### TECHNICAL FIELD

The present disclosure relates to a technique for generating point cloud data having coordinate information.

### BACKGROUND ART

Point cloud data acquired using a mobile mapping system (MMS) or the like is utilized for high-precision maps and structure measurement. The point cloud data merely has simple coordinate information, and it is necessary to extract a target to be measured, for example, a utility pole or a steel tower, from the obtained point cloud data. Hereinafter, this extraction action is referred to as modeling. Various methods have been proposed as modeling techniques, and as one of them, there is a method using machine learning. As one of methods of modeling by machine learning, there is a method of learning feature points by using point cloud data obtained from a measurement target as correct data (see, for example, Patent Literature 1).

Conventionally, in order to create this correct data, the point cloud data is visually checked, and information of being a target is manually specified in the point cloud obtained from the target, and there is a problem that the work time becomes very long. In addition, since training data needs to be point cloud data obtained from the actual environment, there is a problem that training data of a target that is not yet used in the actual environment cannot be created.

### CITATION LIST

### Patent Literature

Patent Literature 1: JP 2019-3527 A

### SUMMARY OF INVENTION

### Technical Problem

An object of the present disclosure is to reduce a work time for creating correct data and to enable creation of correct data even for a target that does not exist in the actual environment.

### Solution to Problem

With a device and method of the present disclosure,
a correction value according to relative positions of a correction data acquisition object and a point cloud measuring instrument is calculated using correction point cloud data obtained by measuring the correction data acquisition object having a known shape with the point cloud measuring instrument and installation positions of the point cloud measuring instrument and the correction data acquisition object at a time of measuring the correction point cloud data,
ideal point cloud coordinates obtained when a measurement target is measured with the point cloud measuring instrument are calculated using simulation data of the measurement target, and
the ideal point cloud coordinates are corrected with a correction value according to relative positions of the measurement target and the point cloud measuring instrument to generate correct point cloud data simulating the measurement target.

Specifically, a program of the present disclosure is a program for causing a computer to be achieved as each functional unit included in the device according to the present disclosure and is a program for causing a computer to execute each step included in a communication method executed by the device according to the present disclosure.

### Advantageous Effects of Invention

According to the present disclosure, it is possible to reduce a work time for manually creating correct data and to create correct data even for a target that does not exist in the actual environment.

### BRIEF DESCRIPTION OF DRAWINGS

FIG. 1 illustrates a system configuration example of the present disclosure.

FIG. 2 is a flowchart illustrating an example of a method of generating correction point cloud data in a correction data generation function unit.

FIG. 3 illustrates an example of acquiring correction point cloud data using a point cloud measuring instrument.

FIG. 4 illustrates an example of correction data.

FIG. 5 illustrates an example of acquiring correction point cloud data using a flat plate.

FIG. 6 is a flowchart illustrating an example of a method of generating correction data in the correction data generation function unit.

FIG. 7 illustrates an example of a probability distribution of Ax.

FIG. 8 is a flowchart illustrating an example of a method of generating correction data in the correction data generation function unit.

FIG. 9 illustrates an example of an approximate curved surface indicating a coordinate error.

FIG. 10 is a flowchart illustrating an example of a method of generating correction point cloud coordinates D in a correct data point cloud generation function unit.

FIG. 11 is an explanatory diagram for generating ideal point cloud coordinates C from 3D CAD data.

FIG. 12 is an explanatory diagram for generating correction point cloud coordinates D from point cloud coordinates C.

FIG. 13 illustrates an example of acquiring correction point cloud data using a mobile point cloud measuring instrument.

FIG. 14 illustrates an example of acquiring correction point cloud data using a mobile point cloud measuring instrument.

FIG. 15 is an explanatory diagram for generating ideal point cloud coordinates C from 3D CAD data.

### DESCRIPTION OF EMBODIMENTS

Hereinafter, embodiments of the present disclosure will be described in detail with reference to the drawings. Note that the present disclosure is not limited to the embodiments described below. These embodiments are merely examples, and the present disclosure can be carried out in forms with various modifications and improvements on the basis of the knowledge of those skilled in the art. Note that components having the same reference numerals in the present specification and the drawings denote the same components.

### (Overall Configuration)

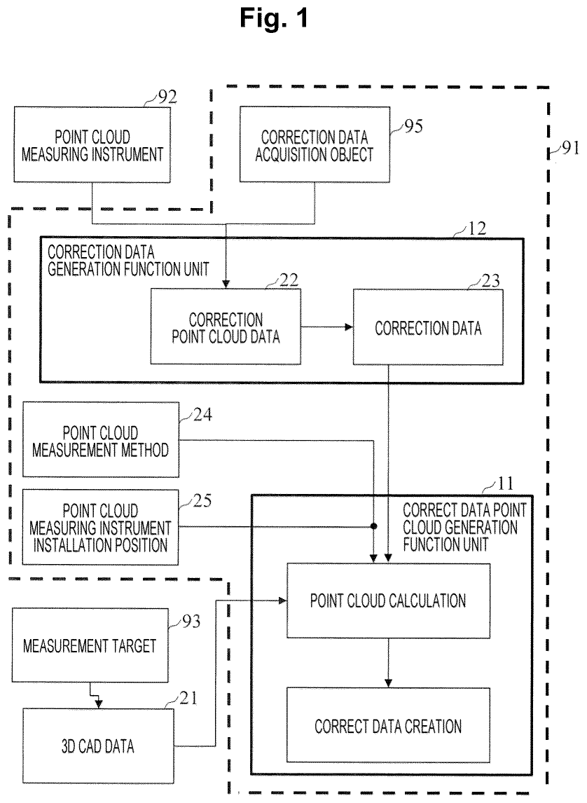

FIG. 1 illustrates a system configuration example of the present disclosure. The system of the present disclosure includes a point cloud data generation device 91, a point cloud measuring instrument 92, a measurement target 93, and a correction data acquisition object 95. The point cloud data generation device 91 includes a correct data point cloud generation function unit 11, a correction data generation function unit 12, and a storage unit 13. The device of the present disclosure can also be achieved by a computer and a program, and the program can be provided by being recorded in a recording medium or via a network.

The present disclosure is
a method of creating correct data used for machine learning that performs modeling on the basis of measured point cloud data, the method including:
calculating correction data 23 according to relative positions of the correction data acquisition object 95 and the point cloud measuring instrument 92 by using correction point cloud data 22 obtained by measuring the correction data acquisition object 95 having a known shape with the point cloud measuring instrument 92 and installation positions of the point cloud measuring instrument 92 and the correction data acquisition object 95 at the time of measuring the correction point cloud data 22;
calculating the ideal point cloud coordinates C obtained when the measurement target 93 is measured with the point cloud measuring instrument 92 using 3D CAD data 21 simulating the measurement target 93;
extracting, from the correction data 23, a correction value according to relative positions of the measurement target 93 and the point cloud measuring instrument 92 used for calculating the point cloud coordinates C; and
calculating the correction point cloud coordinates D by correcting the ideal point cloud coordinates C of the measurement target 93 using the extracted correction value, and generating correct point cloud data simulating the measurement target 93.

The storage unit 13 stores a point cloud measurement method 24 and a point cloud measuring instrument installation position 25.

The point cloud measurement method 24 is data for setting a point cloud measurement method (such as a laser emission method) 24 of the point cloud measuring instrument 92. The point cloud measurement method is, for example, a method in which the point cloud measuring instrument 92 acquires point cloud coordinates A, and for example, a laser emission method can be exemplified.

The point cloud measuring instrument installation position 25 is data for setting an installation position of the point cloud measuring instrument 92. The installation position includes installation position coordinates at which the point cloud measuring instrument 92 is installed at the time of measurement of the point cloud of the correction data acquisition object 95.

The 3D CAD data 21 is simulation data that simulates the measurement target 93. The measurement target 93 is an arbitrary target to be modeled, and for example, a utility pole or a steel tower can be exemplified.

The correction data generation function unit 12 acquires a plurality of patterns of the point cloud of the correction data acquisition object 95 using the point cloud measuring instrument 92, and acquires the correction point cloud data 22. Then, the correction data generation function unit 12 creates the correction data 23 from the correction point cloud data 22.

The 3D CAD data 21 simulating the measurement target 93 is input to the correct data point cloud generation function unit 11. The correct data point cloud generation function unit 11 uses the 3D CAD data 21 to calculate the ideal point cloud coordinates C obtained when the measurement target 93 is measured with the point cloud measuring instrument 92. Then, the correct data point cloud generation function unit 11 creates the correction point cloud coordinates D by adding the correction data 23 to the obtained ideal point cloud coordinates C. Then, the correct data point cloud generation function unit 11 outputs the correction point cloud coordinates D as correct point cloud data.

### First Embodiment

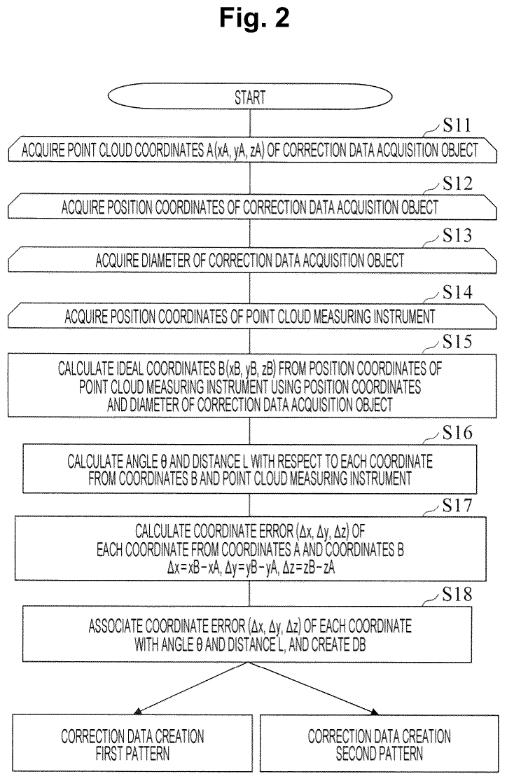

In the present embodiment, a case where the point cloud measuring instrument 92 is of a fixed type will be described. FIG. 2 is a flowchart illustrating an example of a method of creating the correction point cloud data 22 in the correction data generation function unit 12.

Step S11: Point cloud coordinates A (amaze) of the correction data acquisition object 95 are obtained.

Step S12: The installation position coordinates of the correction data acquisition object 95 are acquired.

Step S13: The diameter of the correction data acquisition object 95 is acquired.

Step S14: Installation position coordinates (0,0) of the point cloud measuring instrument 92 are acquired from the point cloud measuring instrument installation position 25.

Step S15: Ideal point cloud coordinates B (x_{B}, y_{B}, z_{B}) are calculated from the installation position coordinates (0,0) of the point cloud measuring instrument 92 using the installation position coordinates and the diameter of the correction data acquisition object 95.

Step S16: A distance L from the point cloud coordinates B to the point cloud measuring instrument 92 and an angle θ at which light from the point cloud measuring instrument 92 is reflected by the point cloud coordinates B are calculated. In the present embodiment, as an example of the angle θ, an example of being an incident angle at which the light from the point cloud measuring instrument 92 is incident on the point cloud coordinates B will be described.

Step S17: Coordinate errors (Δx, Δy, Δz) of the point cloud coordinates A and the point cloud coordinates B are calculated. Here, Δx=x_{B}−x_{A}, Δy=y_{B}−y_{A}, Δz=z_{B}−z_{A} are defined.

Step S18: The coordinate errors Δ (Δx, Δy, Δz) of the point cloud coordinates A and B are associated with the angle θ and the distance L of the point cloud coordinates B to create correction data.

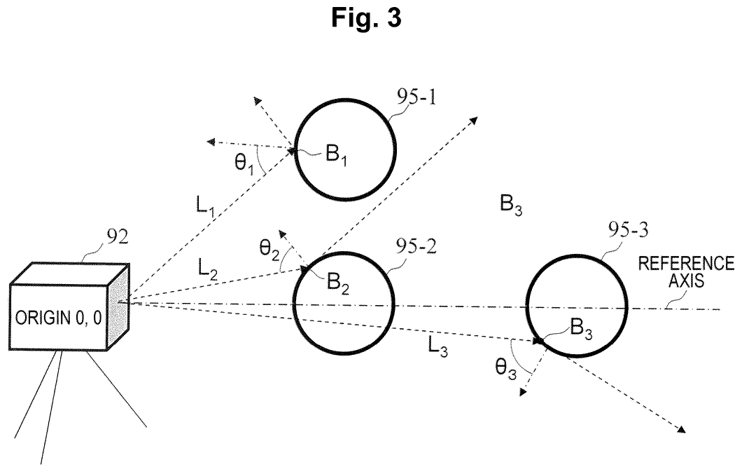

FIG. 3 illustrates an example of acquiring the correction point cloud data using the point cloud measuring instrument 92. The correction data acquisition object 95 is a complete sphere. The correction data acquisition object 95 is measured using a fixed point cloud measuring instrument 92F. At this time, the distances between the correction data acquisition object 95 and the fixed point cloud measuring instrument 92F in the horizontal and vertical directions are changed. For example, the fixed point cloud measuring instrument 92F measures the correction data acquisition object 95 at distances L1, L2, and L3. Thus, it is possible to acquire the point cloud coordinates A of a plurality of patterns having different distances L and angles θ from the correction data acquisition object 95.

Next, the installation position coordinates of the correction data acquisition object 95 and the diameter of the sphere are acquired in advance. The correction data generation function unit 12 calculates the ideally obtained point cloud coordinates B from the obtained point cloud coordinates A and diameter of the sphere. Then, the correction data generation function unit 12 calculates the distance L and the angle θ from the point cloud coordinates B to the point cloud measuring instrument 92F.

Next, a difference between the point cloud coordinates A and the point cloud coordinates B is derived as a coordinate error Δ for each axis of (x, y, z). Thus, coordinate errors Δ (Δx, Δy, Δz) are obtained.

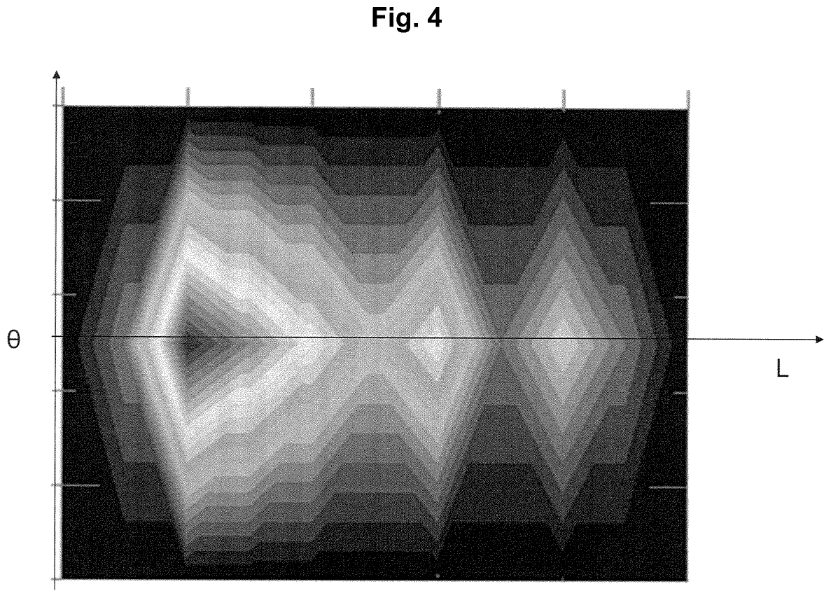

Finally, the correction data 23 is created by associating the distance and angle (L, θ) of the point cloud coordinates B with the coordinate error Δ. FIG. 4 illustrates an example of correction data. Δx included in the correction data 23 is calculated for each combination of the distance L and the angle θ. The same applies to Δy and Δz.

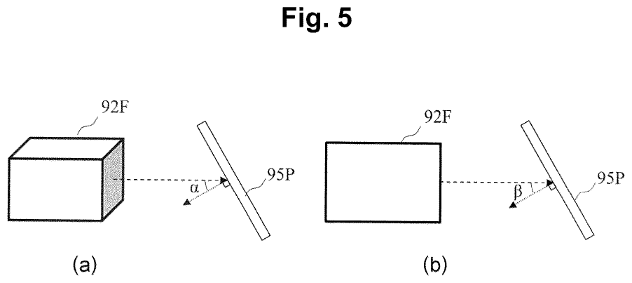

Here, it is desirable to use the same material as that of the measurement target 93 as the material of the correction data acquisition object 95. In addition, the correction data acquisition object 95 may have the same shape as or a different shape from the measurement target 93. For example, the correction data acquisition object 95 may be a flat plate 95P. Note that, in the case of the flat plate 95P, it is desirable that not only the horizontal direction illustrated in FIG. 5(a) and the vertical direction illustrated in FIG. 5(b) are changed, but also installation angles α and β with respect to the point cloud measuring instrument 92 are variable. Thus, the coordinate error Δ according to the angle θ can be more accurately obtained.

### (Correction Data Generation Function Unit 12)

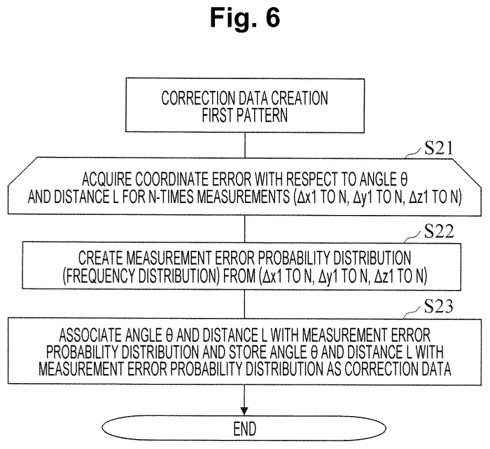

FIG. 6 is a flowchart illustrating a first method of creating the correction data 23 in the correction data generation function unit 12.

Step S21: Δx, Δy, and Δz with respect to θ and L are acquired N times. Thus, the coordinate error Δ with respect to the angle θ and the distance L is acquired for the N-times measurements (Δx₁ to Δx_{N}, Δy₁ to Δy_{N}, Δz₁ to Δz_{N}).

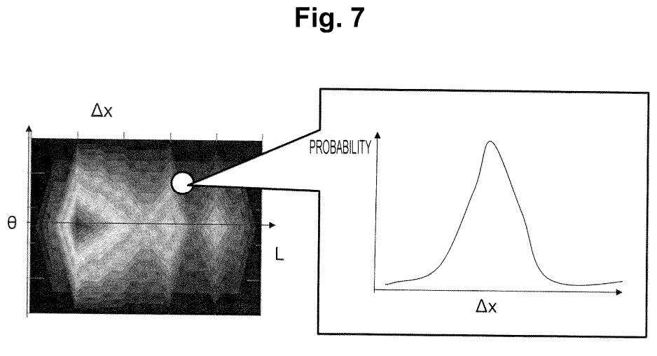

Step S22: A probability distribution (frequency distribution) of the coordinate error Δ is created from (Δx₁ to Δx_{N}, Δy₁ to Δy_{N}, Δz₁ to Δz_{N}). For example, as illustrated in FIG. 7, the probability distribution of Δx is created for Δx acquired N times. For Δy and Δz, the probability distributions are created similarly to Δx. Thus, the probability distributions of the coordinate errors Δ are generated. Then, Δx, Δy, and Δz are determined on the basis of the created probability distributions. For example, the values having the highest probability in the probability distributions are determined as Δx, Δy, and Δz.

Step S23: The angle θ and the distance L, and the coordinate error Δ are associated with each other and stored as the correction data.

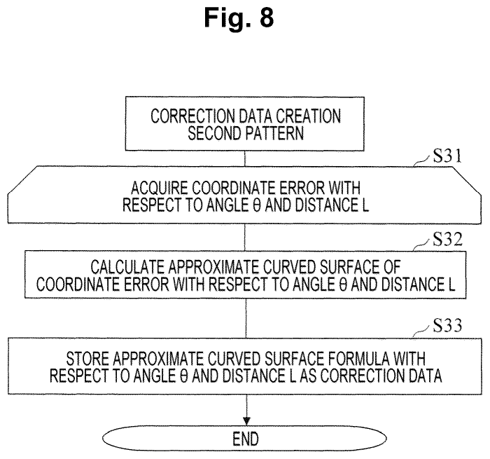

FIG. 8 is a flowchart illustrating a second method of creating the correction data 23 in the correction data generation function unit 12. Unlike the first creation method, the present creation method performs approximation using a value of one measurement with respect to each (L, θ), and in certain (L, θ), correction becomes one value.

Step S31: The coordinate error Δ with respect to the angle θ and the distance L is acquired.

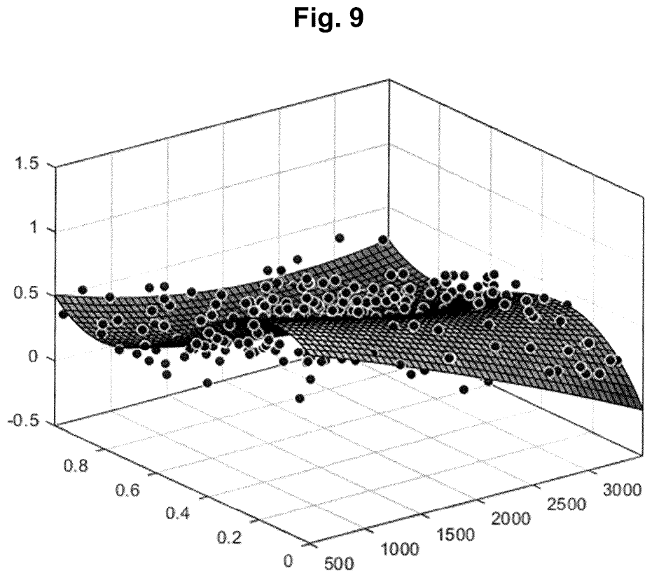

Step S32: An approximate curved surface indicating the coordinate error Δ with respect to the angle θ and the distance L is calculated. FIG. 9 illustrates an example of the approximate curved surface.

Step S33: An approximate curved surface formula with respect to the angle θ and the distance L is stored as the correction data.

Here, in step S32, the values may be uniquely determined by performing approximation on Δx, Δy, and Δz according to θ and L. For example, as the value of θ is closer to θ, Δx, Δy, and Δz are smaller, and as the value is larger, Δx, Δy, and Δz are larger. In addition, as the value of L is closer to θ, Δx, Δy, and Δz are larger, as the value reaches a certain degree, Δx, Δy, and Δz are smaller, and as the value is larger than that, Δx, Δy, and Δz are larger. Therefore, it is desirable to perform decomposition by θ axis and approximate L with a quadratic function or a cubic function.

### (Correct Data Point Cloud Generation Function Unit 11)

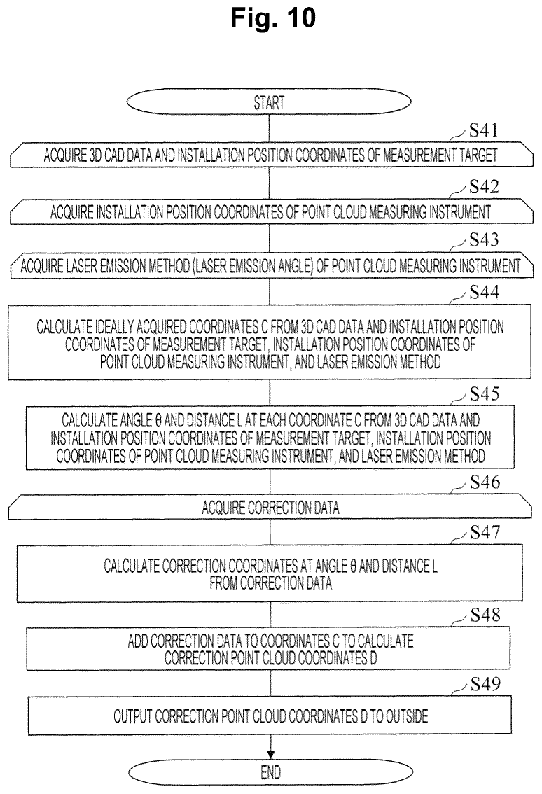

Next, an operation of the correct data point cloud generation function unit 11 will be described with reference to FIGS. 10 to 12. FIG. 10 is a flowchart illustrating an example of a method of creating correction point cloud coordinates D in the correct data point cloud generation function unit 11.

Step S41: The 3D CAD data 21 of the measurement target 93 and the installation position coordinates of the measurement target 93 are acquired.

Step S42: The point cloud measuring instrument installation position 25 is acquired.

Step S43: A laser emission method (laser emission angle) is acquired as the point cloud measurement method 24 of the point cloud measuring instrument 92.

Step S44: The point cloud coordinates C of the measurement target 93 ideally acquired when the measurement target 93 is measured with the point cloud measuring instrument 92 are calculated using the 3D CAD data 21 of the measurement target 93. At this time, the relative positions of the measurement target 93 and the point cloud measuring instrument 92 when the correction point cloud data 22 is acquired are included using the point cloud measuring instrument installation position 25 and the point cloud measurement method 24.

Step S45: The angle θ and the distance L at each point cloud coordinate C are calculated using the installation position coordinates of the measurement target 93, the installation position coordinates of the point cloud measuring instrument 92, and the point cloud measurement method 24.

Step S46: The correction data 23 is acquired.

Step S47: The coordinate errors Δ (Δx, Δy, Δz) at the angle θ and the distance L are calculated from the correction data 23. For example, the coordinate errors Δ (Δx, Δy, Δz) corresponding to (La, θa) are extracted from the correction data 23.

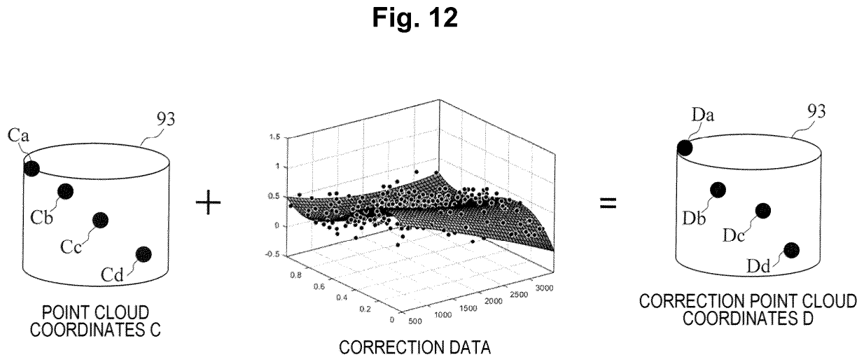

Step S48: As illustrated in FIG. 12, the coordinate errors Δ (Δx, Δy, Δz) are added to the point cloud coordinates C to calculate the correction point cloud coordinates D.

Step S49: The correction point cloud coordinates D are output to the outside as correct point cloud data.

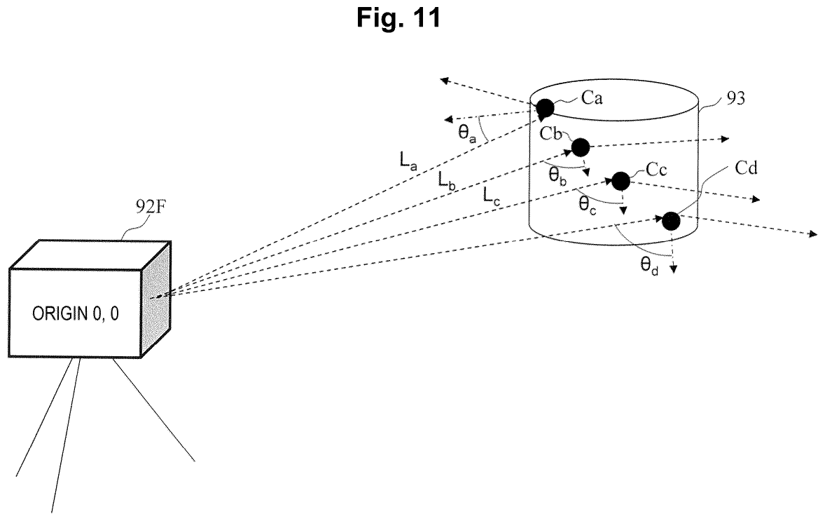

In step S45, for example, in a case where the point cloud measurement method is by the emission of a laser beam, as illustrated in FIG. 11, the distance and the angle θ at point cloud coordinates Ca are (La, θa). In this case, the coordinate error Δ corresponding to (La, θa) is extracted from the correction data 23 (S47), and the extracted coordinate error Δ is added to the point cloud coordinates Ca. Thus, the correction point cloud coordinates D in which the point cloud coordinates Ca are corrected can be calculated.

### Second Embodiment

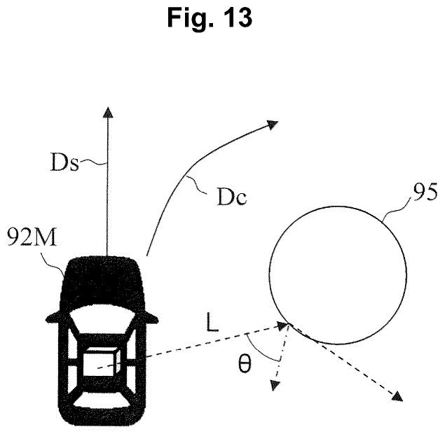

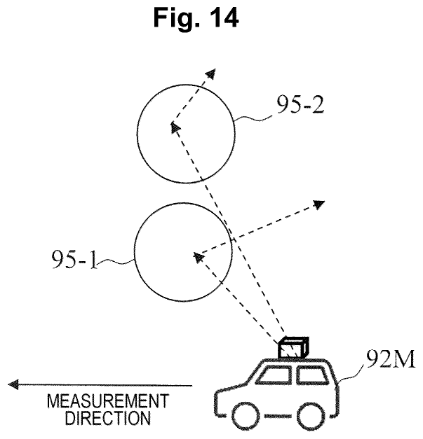

In the present embodiment, a case where the point cloud measuring instrument 92 is a mobile point cloud measuring instrument 92M such as an MMS will be described. FIGS. 13 and 14 illustrate an example of acquiring the correction point cloud data 22 using the mobile point cloud measuring instrument 92M. The correction data acquisition object 95 is a complete sphere.

In the present embodiment, in step S11 illustrated in FIG. 2, the correction data acquisition object 95 is measured using the mobile point cloud measuring instrument 92M in order to acquire the point cloud coordinates A. At this time, as illustrated in FIG. 13, the measurement (traveling) direction of the mobile point cloud measuring instrument 92M with respect to the correction data acquisition object 95 is acquired in two patterns: a straight line Ds and a curve Dc.

Here, the measurement (traveling) direction of the mobile point cloud measuring instrument 92M may be two or more any number of patterns. For example, the curvature of the curve Dc may be further subdivided and acquired. In addition, as illustrated in FIG. 14, it may be acquired using the installation position coordinates of two or more patterns of correction data acquisition objects 95 such as correction data acquisition objects 95-1 and 95-2 by changing the positions of the correction data acquisition object 95 in the horizontal and vertical directions. In addition, the installation position coordinates of the correction data acquisition object 95 may also be subdivided and acquired. Note that, instead of changing the installation position coordinates of the correction data acquisition object 95 in the horizontal direction, the traveling position of the mobile point cloud measuring instrument 92M may be changed.

Also in the present embodiment, the installation position coordinates of the correction data acquisition object 95 and the diameter of the sphere are acquired in advance (S12 to S14). In subsequent step S15, the point cloud coordinates B ideally obtained in each measurement direction are calculated using the installation position coordinates of the correction data acquisition object 95 and the diameter of the sphere. For example, point cloud coordinates B (x_{B}, y_{B}, z_{B}) are calculated for each of the straight line Ds and the curve Dc.

In addition, in step S16, the distance L and the angle θ from the point cloud coordinates B to the point cloud measuring instrument 92 are calculated for each measurement direction. Then, in step S17, the coordinate errors Δ (Δx, Δy, Δz) between the point cloud coordinates A and the point cloud coordinates B are calculated for each measurement direction. Then, in step S18, the coordinate errors Δ (Δx, Δy, Δz) are associated with the distance L and the angle θ of the point cloud coordinates B to create the correction data 23. At this time, the correction data 23 is created for each measurement direction.

Here, the correction data acquisition object 95 is desirably made of the same material as the measurement target 93. In addition, as illustrated in FIGS. 5(a) and 5(b), the correction data acquisition object 95 may be the flat plate 95P.

### (Correction Data Generation Function Unit 12)

The first method of creating the correction data 23 in the correction data generation function unit 12 will be described. Also in the present embodiment, steps S21 to S23 are executed as in the first embodiment. At this time, each step is executed for each measurement direction executed in step S11. Thus, the correction data in which the probability distribution of the coordinate error Δ is associated with the distance L and the angle θ is generated for each measurement direction.

Also in the present embodiment, the correction data generation function unit 12 may create the correction data using the second creation method illustrated in FIG. 8. Thus, approximation can be performed using a value of one measurement with respect to each (L, θ), and in certain (L, θ), correction can be made to one value.

### (Correct Data Point Cloud Generation Function Unit 11)

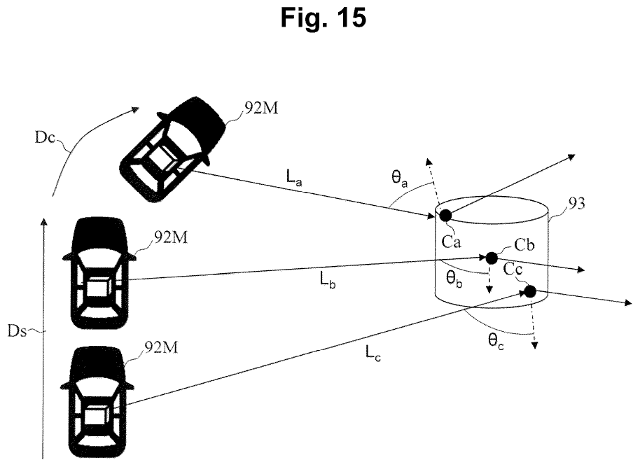

Next, with reference to FIG. 15, an operation of the correct data point cloud generation function unit 11 will be described. The 3D CAD data 21 of the measurement target 93 is acquired (S41), the point cloud measuring instrument installation position 25 is acquired (S42), the point cloud measurement method 24 is acquired (S43), and the ideally acquired point cloud coordinates C are calculated from the 3D CAD data 21 (S44).

Further, the distance L and the angle θ at the point cloud coordinates C are calculated using the point cloud measuring instrument installation position 25 and the point cloud measurement method 24 (S45). For example, as illustrated in FIG. 15, the distance and angle (La, θa) at the point cloud coordinates Ca and the distance and angle (Lb, θb) at point cloud coordinates Cb are calculated.

Next, by using the correction data 23 (S46), the coordinate errors Δ (Δx, Δy, Δz) at the point cloud coordinates Ca are obtained from (La, θa) (S47). Then, as illustrated in FIG. 12, the coordinate errors Δ (Δx, Δy, Δz) according to (La, θa) are added to the point cloud coordinates Ca to calculate correction point cloud coordinates Da at the point cloud coordinates Ca (S48). This processing is performed on all the point cloud coordinates C.

Here, in the present embodiment, the correction data in which the angle θ and the distance L are associated with the probability distribution of the coordinate error Δ is generated for each measurement direction. Therefore, in the present embodiment, the correction point cloud coordinates D are calculated for each measurement direction. For example, when the measurement direction is the straight line Ds, correction coordinates of the straight line are used, and when the measurement direction is the curve Dc, correction coordinates of the curve are used. Finally, the correction point cloud coordinates D are output for each measurement direction to the outside and stored as a correct data point cloud (S49).

As described above, since the point cloud data generation device 91 of the present embodiment includes the correct data point cloud generation function unit 11, it is possible to automatically create the correct point cloud data using the correction data 23. Thus, according to the present embodiment, it is not necessary to manually create the correct data from the point cloud, and the work time for manually creating the correct data can be reduced.

Further, since the point cloud data generation device 91 of the present embodiment corrects the point cloud coordinates C using the coordinate error Δ according to the angle θ and the distance L, simulation data close to actual data in consideration of a measurement error of the point cloud measuring instrument 92 becomes possible. Thus, in the present embodiment, it is possible to create correct data even when the measurement target 93 is not in an actual facility. Thus, the present embodiment enables reproduction of an actual facility using 3D CAD, and enables generation of correct data for machine learning by point cloud simulation in consideration of a measurement error of the point cloud measuring instrument 92.

### INDUSTRIAL APPLICABILITY

The present disclosure can be applied to information and communication industries.

### REFERENCE SIGNS LIST

11 Correct data point cloud generation function unit
12 Correction data generation function unit
21 3D CAD data
22 Correction point cloud data
23 Correction data
24 Point cloud measurement method
25 Point cloud measuring instrument installation position
91 Point cloud data generation device
92 Point cloud measuring instrument
92F Fixed point cloud measuring instrument
92M Mobile point cloud measuring instrument
93 Measurement target
95, 95-1, 95-2, 95-3, 95P Correction data acquisition object

1. A device, wherein
a correction value according to relative positions of a correction data acquisition object and a point cloud measuring instrument is calculated using correction point cloud data obtained by measuring the correction data acquisition object having a known shape with the point cloud measuring instrument and installation positions of the point cloud measuring instrument and the correction data acquisition object at a time of measuring the correction point cloud data,
ideal point cloud coordinates obtained when a measurement target is measured with the point cloud measuring instrument are calculated using simulation data of the measurement target, and
the ideal point cloud coordinates are corrected with a correction value according to relative positions of the measurement target and the point cloud measuring instrument to generate correct point cloud data simulating the measurement target.

2. The device according to claim 1, wherein
point cloud coordinates A are measured by measuring the correction point cloud data obtained by measuring the correction data acquisition object with a point cloud measuring instrument installed at a plurality of installation positions having different distances,
ideal point cloud coordinates B when the correction data acquisition object is measured are calculated using the point cloud coordinates A and a shape of the correction data acquisition object,
a distance L from the point cloud coordinates B to the point cloud measuring instrument is calculated using an installation position of the point cloud measuring instrument,
an angle θ at which light from the point cloud measuring instrument is reflected at the point cloud coordinates B is calculated using the installation position of the point cloud measuring instrument and the shape of the correction data acquisition object,
a coordinate error Δ of the point cloud coordinates B is calculated by calculating a difference between the point cloud coordinates A and the point cloud coordinates B, and
the coordinate error Δ at the point cloud coordinates B is associated with the distance L and the angle θ at the point cloud coordinates B and is output as the correction value.

3. The device according to claim 2, wherein
an approximate curved surface indicating the coordinate error Δ with respect to the angle θ and the distance L is calculated, and the calculated approximate curved surface is output as the correction value.

4. The device according to claim 3, wherein
the approximate curved surface is obtained by decomposing the coordinate error Δ with respect to the angle θ and the distance L by the angle θ and approximating the distance L by a quadratic function or a cubic function.

5. The device according to claim 1, wherein
the correction data acquisition object is made of a same material as a material of the measurement target.

6. A method comprising:
calculating a correction value according to relative positions of a correction data acquisition object and a point cloud measuring instrument using correction point cloud data obtained by measuring the correction data acquisition object having a known shape with the point cloud measuring instrument and installation positions of the point cloud measuring instrument and the correction data acquisition object at a time of measuring the correction point cloud data;
calculating ideal point cloud coordinates obtained when a measurement target is measured with the point cloud measuring instrument using simulation data of the measurement target; and
correcting the ideal point cloud coordinates with a correction value according to relative positions of the measurement target and the point cloud measuring instrument to generate correct point cloud data simulating the measurement target.

7. A non-transitory computer-readable medium having computer-executable instructions that, upon execution of the instructions by a processor of a computer, cause the computer to function as the device according to claim 1.
